(19) United States
(12) Patent Application Publication
(10) Pub. No.: US 2026/0075756 A1
(43) Pub. Date: Mar. 12, 2026

(54) LIQUID-COOLING HEAT DISSIPATION PLATE HAVING UNEVEN FIN DENSITY AND UNEQUAL FIN HEIGHT

(71) Applicant: AMULAIRE THERMAL TECHNOLOGY, INC., New Taipei City (TW)

(72) Inventors: YI-HSIN HUANG, New Taipei City (TW); KUO-WEI LEE, New Taipei City (TW); TZE-YANG YEH, New Taipei City (TW); CHIEN-CHENG WU, New Taipei City (TW); CHUN-LUNG WU, New Taipei City (TW); CHING-MING YANG, New Taipei City (TW); MING-HSUAN CHANG, Taoyuan City (TW)

(21) Appl. No.: 18/826,365

(22) Filed: Sep. 6, 2024

(51) Int. Cl. H05K 7/20

(52) U.S. Cl. CPC H05K 7/20263; H05K 7/20936

(57) ABSTRACT

A liquid-cooling heat dissipation plate having an uneven fin density and an unequal fin height includes a heat dissipation plate body having first and second heat dissipation surfaces opposite to each other, and multiple full-height fins and non-full-height fins formed on the second heat dissipation surface. The heat dissipation plate body is divided into a first to an N-th heat dissipation region along a cooling-liquid flowing direction. Multiple chips correspond in position respectively to the first to the N-th heat dissipation region. Each heat dissipation region is divided into a front region, a heat source region, and a rear region according to the cooling-liquid flowing direction. In each heat dissipation region, a fin density of the heat source region is greater than or equal to that of the rear region, and the fin density of the heat source region is greater than that of the front region.

### FIELD OF THE DISCLOSURE

The present disclosure relates to a liquid-cooling heat dissipation plate, and more particularly to a liquid-cooling heat dissipation plate having an uneven fin density and an unequal fin height.

### BACKGROUND OF THE DISCLOSURE

Coolers are widely used in various products. Generally, high-end products adopt water/liquid-cooling coolers for having advantages of quietness and stable cooling performance (as compared with air-cooling coolers). However, as an operating speed of chips of a power module in an electric vehicle increases, existing liquid-cooling coolers can no longer satisfy the heat dissipation requirements of these chips of the power module in the electric vehicle. Therefore, how to achieve heat dissipation more effectively via the liquid-cooling heat dissipation technology has long been an issue to be solved in the relevant industry.

### SUMMARY OF THE DISCLOSURE

In response to the above-referenced technical inadequacy, the present disclosure provides a liquid-cooling heat dissipation plate having an uneven fin density and an unequal fin height.

In order to solve the above-mentioned problem, one of the technical aspects adopted by the present disclosure is to provide a liquid-cooling heat dissipation plate having an uneven fin density and an unequal fin height, which is disposed in a closed-loop liquid-cooling cooler. The liquid-cooling heat dissipation plate includes a heat dissipation plate body, a plurality of full-height fins, and a plurality of non-full-height fins. The heat dissipation plate body has a first heat dissipation surface and a second heat dissipation surface that are opposite to each other, and a plurality of chip bonding regions are formed on the first heat dissipation surface, so as to bond with a plurality of chips. The second heat dissipation surface is configured to be in contact with a cooling liquid, and the full-height fins and the non-full-height fins are formed on the second heat dissipation surface of the heat dissipation plate body. The heat dissipation plate body is divided into a first heat dissipation region to an N-th heat dissipation region along a cooling-liquid flowing direction, N is an integer greater than or equal to three, and the chips correspond in position respectively to the first heat dissipation region to the N-th heat dissipation region. Each of the heat dissipation regions is divided into a front region, a heat source region, and a rear region according to the cooling-liquid flowing direction. In each of the heat dissipation regions, a fin density of the heat source region is greater than or equal to a fin density of the rear region, and the fin density of the heat source region is greater than a fin density of the front region.

In one of the possible or preferred embodiments, the heat dissipation plate body is made of one of copper, a copper alloy, aluminum, and an aluminum alloy.

In one of the possible or preferred embodiments, the heat dissipation plate body is integrally formed by metal injection molding or forging.

In one of the possible or preferred embodiments, the fin density of the front region in each of the heat dissipation regions is 70% to 85% of the fin density of the heat source region, the fin density of the rear region in each of the heat dissipation regions is 80% to 100% of the fin density of the heat source region, and the fin density of the rear region in each of the heat dissipation regions is greater than the fin density of the front region.

In one of the possible or preferred embodiments, at least one of a fin average height of the front region and a fin average height of the rear region is 85% to 100% of a fin average height of the heat source region in each of the heat dissipation regions.

In one of the possible or preferred embodiments, only a fin average height of the rear region in the N-th heat dissipation region is 100% of a fin average height of the heat source region in the N-th heat dissipation region.

In one of the possible or preferred embodiments, the fin densities of the heat source regions in the first heat dissipation region to the N-th heat dissipation region are increased along the cooling-liquid flowing direction.

In one of the possible or preferred embodiments, a projection area of the heat source region in each of the heat dissipation regions is greater than a projection area of each of the chip bonding regions, and a distance between a side of each of the chip bonding regions and a side of a corresponding one of the heat source regions is not greater than 5 mm.

In one of the possible or preferred embodiments, the rear region in each of the heat dissipation regions is divided from the front region in a subsequent one of the heat dissipation regions by a midline of a distance between the heat source region in each of the heat dissipation regions and the heat source region in the subsequent one of the heat dissipation regions.

In one of the possible or preferred embodiments, the chip is a power chip of a six-pack power module.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of a liquid-cooling heat dissipation plate according to a first embodiment of the present disclosure;

FIG. 2 is a schematic top view of the liquid-cooling heat dissipation plate according to the first embodiment of the present disclosure;

FIG. 3 is a schematic partial view of full-height fins and non-full-height fins of the liquid-cooling heat dissipation plate according to the first embodiment of the present disclosure;

FIG. 4 is another schematic partial view of the full-height fins and the non-full-height fins of the liquid-cooling heat dissipation plate according to the first embodiment of the present disclosure;

FIG. 5 is a schematic side view of the liquid-cooling heat dissipation plate according to a second embodiment of the present disclosure; and

FIG. 6 is a schematic side view of the liquid-cooling heat dissipation plate according to a third embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

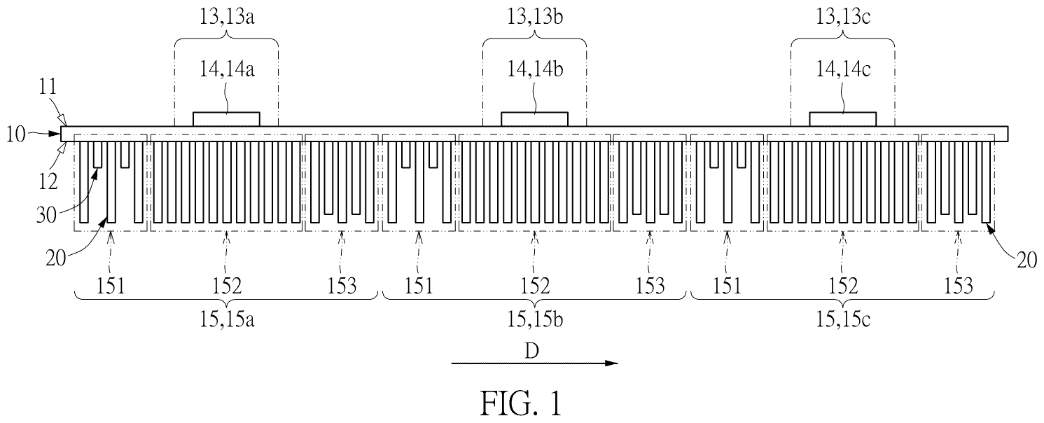

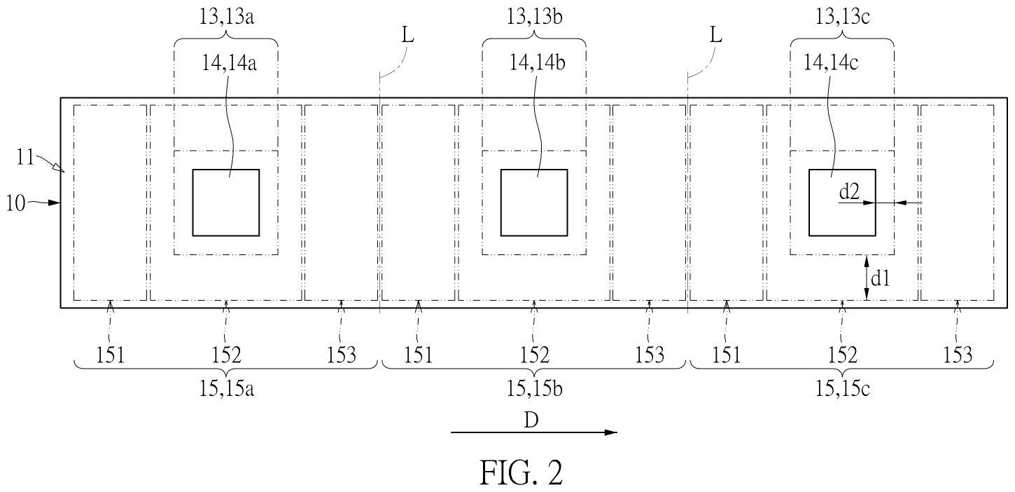

Referring to FIG. 1 to FIG. 4, one embodiment of the present disclosure provides a liquid-cooling heat dissipation plate having an uneven fin density and an unequal fin height. The liquid-cooling heat dissipation plate is disposed in a closed-loop liquid-cooling cooler, and implementations of the closed-loop liquid-cooling cooler are not limited. As shown in FIG. 1 and FIG. 2, the liquid-cooling heat dissipation plate provided in the embodiment of the present disclosure essentially includes a heat dissipation plate body 10, a plurality of full-height fins 20, and a plurality of non-full-height fins 30. A fin height of one non-full-height fin 30 can be 25% to 95% of a fin height of one full-height fin 20.

The heat dissipation plate body 10 of the present embodiment is made of a high thermal conductive material, such as copper, a copper alloy, aluminum, and an aluminum alloy. In addition, the heat dissipation plate body 10 has a first heat dissipation surface 11 and a second heat dissipation surface 12 that are opposite to each other. A plurality of chip bonding regions 13 (i.e., a first chip bonding region 13a, a second chip bonding region 13b, and a third chip bonding region 13c) are formed on the first heat dissipation surface 11, so as to bond with a plurality of chips 14. The second heat dissipation surface 12 is configured to be in contact with a cooling liquid (which can be, for example, water or ethylene glycol, but is not shown in the figures). The chip 14 of the present embodiment can be a power chip of a six-pack power module.

In the present embodiment, the full-height fins 20 and the non-full-height fins 30 are integrally formed on the second heat dissipation surface 12 of the heat dissipation plate body 10. Specifically, the full-height fins 20, the non-full-height fins 30, and the heat dissipation plate body 10 can be integrally formed by metal injection molding (MIM), thereby having material continuity. The heat dissipation plate body 10 can also be integrally formed by forging.

The heat dissipation plate body 10 of the present embodiment is divided into a first to an N-th heat dissipation region 15 along a cooling-liquid flowing direction D, and N is an integer greater than or equal to three. Furthermore, the chips 14 correspond in position respectively to the first to the N-th heat dissipation region 15. In other words, the chip bonding regions 13 correspond in position respectively to the first to the N-th heat dissipation region 15.

Specifically, the heat dissipation plate body 10 of the present embodiment is divided into the first to the third heat dissipation region 15 (i.e., a first heat dissipation region 15a, a second heat dissipation region 15b, and a third heat dissipation region 15c) along the cooling-liquid flowing direction D. The three chips 14 (i.e., a first chip 14a, a second chip 14b, and a third chip 14c) correspond in position to the first heat dissipation region 15a, the second heat dissipation region 15b, and the third heat dissipation region 15c, respectively. That is to say, the cooling-liquid flowing direction D refers to flowing in a direction from the first chip 14a to the third chip 14c (with the second chip 14b in-between). A power of each of the first chip 14a, the second chip 14b, and the third chip 14c can be the same as or different from each other. Furthermore, each heat dissipation region 15 (i.e., the first heat dissipation region 15a, the second heat dissipation region 15b, and the third heat dissipation region 15c) is divided into a front region 151, a heat source region 152, and a rear region 153 according to the cooling-liquid flowing direction D. In each heat dissipation region 15, a fin density of the heat source region 152 is greater than or equal to a fin density of the rear region 153, and the fin density of the heat source region 152 is greater than a fin density of the front region 151. Through the unequal fin height and division of each heat dissipation region 15 into the front region 151, the heat source region 152, and the rear region 153 having the uneven fin density according to the cooling-liquid flowing direction D, heat dissipation can be specifically performed on a heat source of each heat dissipation region 15. In addition, a flow velocity of the cooling liquid can be increased when travelling through the front region 151 in each heat dissipation region 15 along the cooling-liquid flowing direction D, thereby quickly guiding the cooling liquid to the subsequent two regions and allowing an overall heat dissipation temperature to be even.

In order for the overall heat dissipation temperature to be more even, the fin density of the front region 151 in each heat dissipation region 15 is 70% to 85% of the fin density of the heat source region 152, the fin density of the rear region 153 in each heat dissipation region 15 is 80% to 100% of the fin density of the heat source region 152, and the fin density of the rear region 153 in each heat dissipation region 15 is greater than the fin density of the front region 151.

In each heat dissipation region 15, a fin average height of the front region 151 is 85% to 100% of a fin average height of the heat source region 152, or a fin average height of the rear region 153 is 85% to 100% of the fin average height of the heat source region 152. That is to say, at least one of the fin average height of the front region 151 and the fin average height of the rear region 153 is 85% to 100% of the fin average height of the heat source region 152 in each heat dissipation region 15.

As shown in FIG. 2, a projection area of the heat source region 152 in each heat dissipation region 15 is greater than a projection area of each chip bonding region 13, and a distance d1 between a side of each chip bonding region 13 and a side of a corresponding one of the heat source regions 152 is not greater than 5 mm. Specifically, the projection area of the chip bonding region 13 can be equal to or greater than a projection area of a corresponding one of the chips 14. When the projection area of the chip bonding region 13 is greater than the projection area of the corresponding one of the chips 14, a distance d2 between a side of the chip 14 and the side of the chip bonding region 13 is not greater than 1 mm.

The rear region 153 in each heat dissipation region 15 is divided from the front region 151 in a subsequent one of the heat dissipation regions 15 by a midline L of a distance between the heat source region 152 in each heat dissipation region 15 and the heat source region 152 in the subsequent one of the heat dissipation regions 15. That is to say, the midline L of the distance between two adjacent ones of the heat source regions 152 can be used for dividing and obtaining the rear region 153 and the front region 151 of the two adjacent ones of the heat source regions 152.

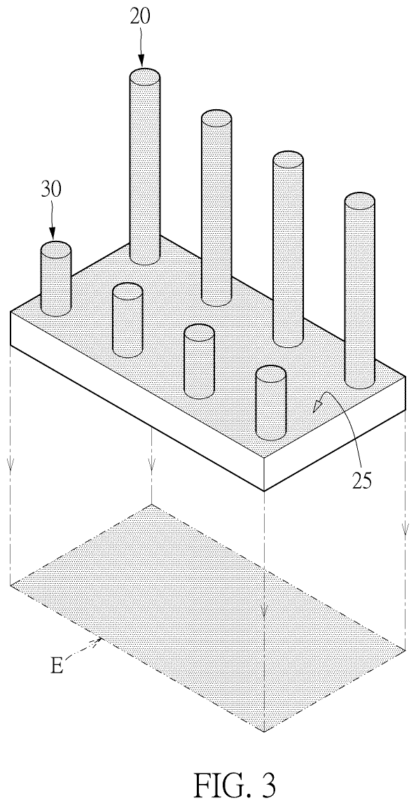

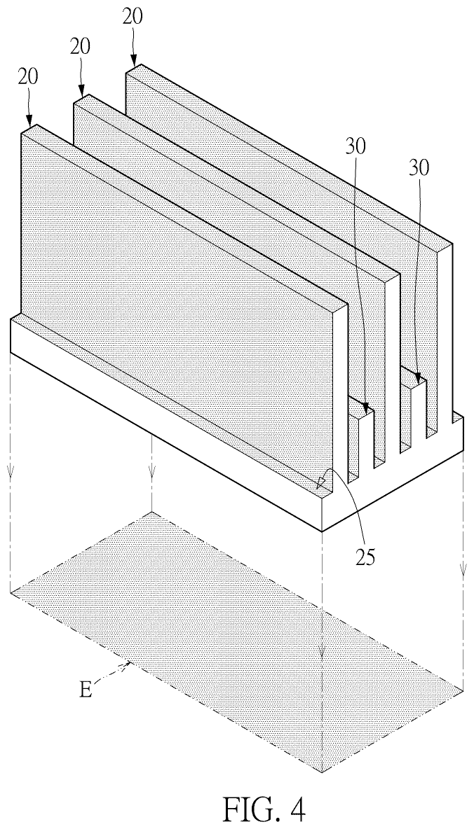

As shown in FIG. 3, the full-height fins 20 and the non-full-height fins 30 of the present embodiment can be, for example, pin fins. The fin density mentioned in the present embodiment is defined as a value of dividing a total surface area of the fins in each region by a rectangular projection area E of each region. Specifically, the total surface area of the fins mentioned in the present embodiment is defined as a value of a surface area of the fins (e.g., the full-height fins 20 and the non-full-height fins 30) in each region plus an area of a bottom surface 25 that is not occupied by these fins in each region. As shown in FIG. 4, the full-height fins 20 and the non-full-height fins 30 of the present embodiment can also be, for example, plate fins.

### Second Embodiment

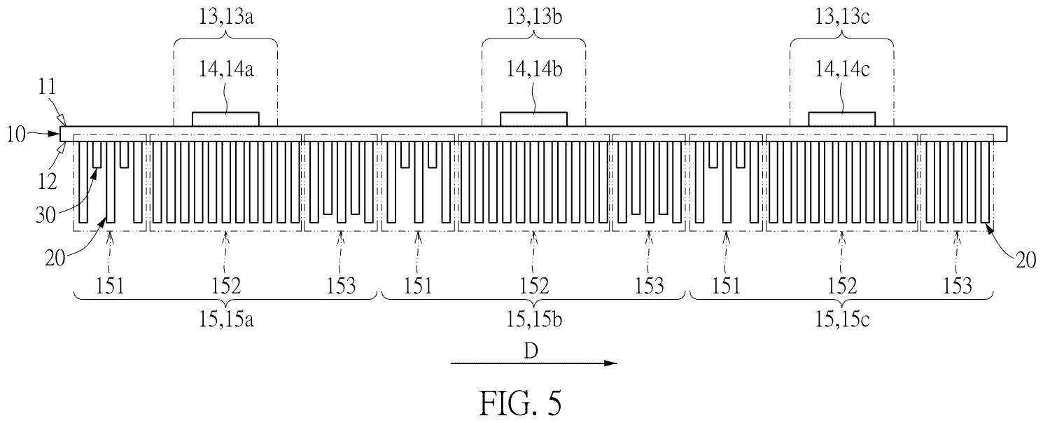

The second embodiment of the present disclosure is shown in FIG. 5. The present embodiment is substantially the same as the first embodiment, and the difference therebetween is illustrated below.

In the present embodiment, only the fin average height of the rear region 153 in the N-th heat dissipation region 15 (i.e., the third heat dissipation region 15c) is 100% of the fin average height of the heat source region 152 in the N-th heat dissipation region 15.

### Third Embodiment

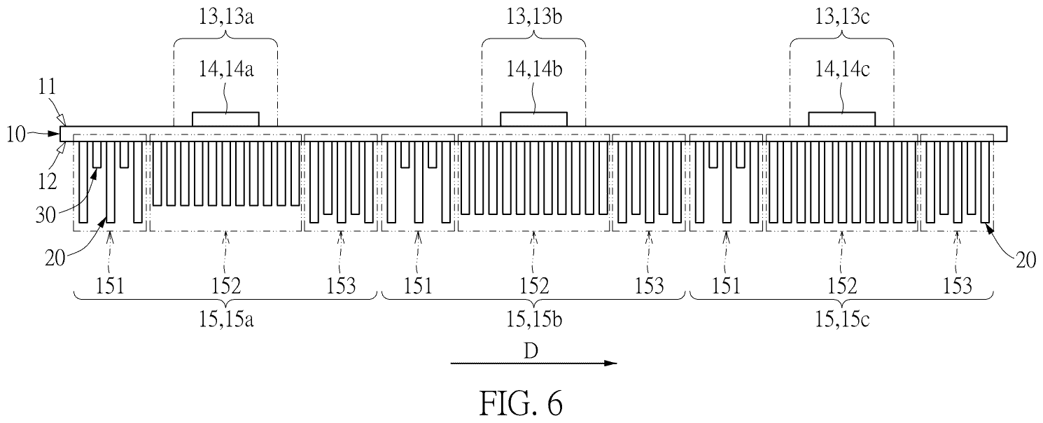

The third embodiment of the present disclosure is shown in FIG. 6. The present embodiment is substantially the same as the first embodiment, and the difference therebetween is illustrated below.

In the present embodiment, the fin densities of the heat source regions 152 in the first to the N-th heat dissipation region 15 (i.e., the first heat dissipation region 15a, the second heat dissipation region 15b, and the third heat dissipation region 15c) are increased along the cooling-liquid flowing direction D. That is to say, the fin density of the heat source region 152 in the third heat dissipation region 15c is greater than the fin density of the heat source region 152 in the second heat dissipation region 15b, and the fin density of the heat source region 152 in the second heat dissipation region 15b is greater than the fin density of the heat source region 152 in the first heat dissipation region 15a.

### Beneficial Effects of the Embodiments

In conclusion, the liquid-cooling heat dissipation plate having the uneven fin density and the unequal fin height provided by the present disclosure is disposed a closed-loop liquid-cooling cooler. The liquid-cooling heat dissipation plate includes a heat dissipation plate body, a plurality of full-height fins, and a plurality of non-full-height fins. The heat dissipation plate body has a first heat dissipation surface and a second heat dissipation surface that are opposite to each other, and a plurality of chip bonding regions are formed on the first heat dissipation surface, so as to bond with a plurality of chips. The second heat dissipation surface is configured to be in contact with a cooling liquid. The full-height fins and the non-full-height fins are formed on the second heat dissipation surface of the heat dissipation plate body, and the heat dissipation plate body is divided into a first heat dissipation region to an N-th heat dissipation region along a cooling-liquid flowing direction. The chips correspond in position respectively to the first heat dissipation region to the N-th heat dissipation region. Each of the heat dissipation regions is divided into a front region, a heat source region, and a rear region according to the cooling-liquid flowing direction. In each of the heat dissipation regions, a fin density of the heat source region is greater than or equal to a fin density of the rear region, and the fin density of the heat source region is greater than a fin density of the front region. Through the unequal fin height and division of each of the heat dissipation regions into the front region, the heat source region, and the rear region having the uneven fin density according to the cooling-liquid flowing direction, heat dissipation can be specifically performed on a heat source of each of the heat dissipation regions. In addition, a flow velocity of the cooling liquid can be increased when travelling through the front region in each of the heat dissipation regions along the cooling-liquid flowing direction, thereby quickly guiding the cooling liquid to the subsequent two regions and allowing an overall heat dissipation temperature to be even.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A liquid-cooling heat dissipation plate having an uneven fin density and an unequal fin height, which is disposed in a closed-loop liquid-cooling cooler, the liquid-cooling heat dissipation plate comprising:
a heat dissipation plate body;
a plurality of full-height fins; and
a plurality of non-full-height fins;
wherein the heat dissipation plate body has a first heat dissipation surface and a second heat dissipation surface that are opposite to each other, and a plurality of chip bonding regions are formed on the first heat dissipation surface, so as to bond with a plurality of chips; wherein the second heat dissipation surface is configured to be in contact with a cooling liquid, and the full-height fins and the non-full-height fins are formed on the second heat dissipation surface of the heat dissipation plate body; wherein the heat dissipation plate body is divided into a first heat dissipation region to an N-th heat dissipation region along a cooling-liquid flowing direction, N is an integer greater than or equal to three, and the chips correspond in position respectively to the first heat dissipation region to the N-th heat dissipation region; wherein each of the heat dissipation regions is divided into a front region, a heat source region, and a rear region according to the cooling-liquid flowing direction; wherein, in each of the heat dissipation regions, a fin density of the heat source region is greater than or equal to a fin density of the rear region, and the fin density of the heat source region is greater than a fin density of the front region.

2. The liquid-cooling heat dissipation plate according to claim 1, wherein the heat dissipation plate body is made of one of copper, a copper alloy, aluminum, and an aluminum alloy.

3. The liquid-cooling heat dissipation plate according to claim 1, wherein the heat dissipation plate body is integrally formed by metal injection molding or forging.

4. The liquid-cooling heat dissipation plate according to claim 1, wherein the fin density of the front region in each of the heat dissipation regions is 70% to 85% of the fin density of the heat source region, the fin density of the rear region in each of the heat dissipation regions is 80% to 100% of the fin density of the heat source region, and the fin density of the rear region in each of the heat dissipation regions is greater than the fin density of the front region.

5. The liquid-cooling heat dissipation plate according to claim 1, wherein at least one of a fin average height of the front region and a fin average height of the rear region is 85% to 100% of a fin average height of the heat source region in each of the heat dissipation regions.

6. The liquid-cooling heat dissipation plate according to claim 1, wherein only a fin average height of the rear region in the N-th heat dissipation region is 100% of a fin average height of the heat source region in the N-th heat dissipation region.

7. The liquid-cooling heat dissipation plate according to claim 1, wherein the fin densities of the heat source regions in the first heat dissipation region to the N-th heat dissipation region are increased along the cooling-liquid flowing direction.

8. The liquid-cooling heat dissipation plate according to claim 1, wherein a projection area of the heat source region in each of the heat dissipation regions is greater than a projection area of each of the chip bonding regions, and a distance between a side of each of the chip bonding regions and a side of a corresponding one of the heat source regions is not greater than 5 mm.

9. The liquid-cooling heat dissipation plate according to claim 1, wherein the rear region in each of the heat dissipation regions is divided from the front region in a subsequent one of the heat dissipation regions by a midline of a distance between the heat source region in each of the heat dissipation regions and the heat source region in the subsequent one of the heat dissipation regions.

10. The liquid-cooling heat dissipation plate according to claim 1, wherein the chip is a power chip of a six-pack power module.
